(19) United States
(12) Patent Application Publication
(10) Pub. No.: US 2009/0027084 A1
(43) Pub. Date: Jan. 29, 2009

(54) RAPID RESPONSE PUSH-UP PULL-DOWN BUFFER CIRCUIT

(76) Inventor: Yong Ho KONG, Seoul (KR)

Correspondence Address: LADAS & PARRY LLP, 224 SOUTH MICHIGAN AVENUE, SUITE 1600, CHICAGO, IL, 60604, US

(21) Appl. No.: 12/110,654

(22) Filed: Apr. 28, 2008

(30) Foreign Application Priority Data
Jul. 26, 2007 (KR) 10-2007-0075255

(51) Int. Cl. H03K 19/082

(52) U.S. Cl. 326/91

(57) ABSTRACT

A rapid response push-up pull-down buffer circuit configuration is used as an output buffer of a semiconductor memory device. The buffer circuit includes a pre-driver outputting a driving signal in response to an input data. The buffer circuit also includes an output driver driving an output signal in response to the driving signal which also has a driving strength adjusted in response to a level of the output signal. Accordingly, the driving strength can be automatically controlled in response to a level of the output signal which also results in enhancing the response speed of the buffer circuit.

### CROSS-REFERENCE TO RELATED APPLICATIONS

The present application claims priority to Korean patent application number 10-2007-0075255 filed on Jul. 26, 2007, which is incorporated herein by reference in its entirety.

### BACKGROUND OF THE INVENTION

The present invention relates to a buffer circuit, and more particularly to a buffer circuit capable of being used as an output buffer of a semiconductor memory device.

In general, a semiconductor memory device is equipped with various buffer circuits. As an example, when outputting an internal data to the outside via a pad, the output buffer amplifies the data to a sufficient level for outputting.

The output buffer is conventionally configured, as depicted in FIG. 1, to drive data DATA to generate any one of a pull-up driving signal ENP1, ENP2 or any one of a pull-down driving signal ENN1, ENN2 via a pre-driver 12, and output an output data DOUT having a prescribed voltage level by pull-up or pull-down driving in response to the pull up driving signal ENP1 or the pull down driving signal ENN1 via the output driver 14, as shown in FIG. 1.

If the pull-up driving strength of PMOS transistor P1 of an output driver 14 is controlled by the pull-up operation signal ENP1 and by the pull-down driving strength of a NMOS transistor N1 of an output driver 14 is controlled by a pull-down driving signal ENN1 are not sufficient, then problems would arise. One problem in particular is that the response time of the output buffer of the output data DOUT is delayed or at least not normally outputted until the output data DOUT signal is sufficiently increased or decreased to an acceptable and normal level.

In order to address such problems, a conventional output buffer is equipped with a fuse box 10. If a fuse provided in the fuse box 10 is cut, any one of fuse signals FUSEP, FUSEN is provided to the pre-driver 12 so that a sub pull-up driving signal ENP2 or sub pull-down driving signal ENN2 is output.

Further, if the sub pull-up driving signal ENP2 is output, a PMOS transistor P2 is turned on by the sub pull-up driving signal ENP2 so that the pull-up driving strength of the output driver 14 is higher, and if the sub pull-down driving signal ENN2 is output, a NMOS transistor N2 is turned on by the sub pull-down driving signal ENN2 so that the pull-down driving strength of the output driver 14 is higher.

However, since the conventional buffer circuit is additionally equipped with such a fuse box 10, then a concomitant problem that the buffer circuit necessarily requires a larger area.

Further, there are also problems in that the operations, necessarily become troublesome and time consuming, because a fuse cutting operation is required in order to adjust the driving strength of the output driver 14.

### SUMMARY OF THE INVENTION

There is provided a buffer circuit having reduced area while controlling a driving strength of a driver.

There is provided a buffer circuit capable of controlling a driving strength of a driver in a simple way.

There is provided a buffer circuit capable of reducing a response time which is required to control a driving strength of a driver.

A buffer circuit according to one embodiment of the present invention comprises a pre-driver outputting a driving signal in response to an input data; and an output driver driving an output signal in response to the driving signal wherein the output driver having a strength of the driving adjusted in response to a level of the output signal.

Preferably, the pre-driver outputs a pull-up driving signal or a pull-down driving signal as the driving signal of the pre-driver to correspond with a level of the input signal.

The output driver comprises a sub-driving unit which sub-drives the output signal in response to a level of the output signal to adjust the driving strength.

Further, the output driver comprises a main driving unit pull-up driving or pull-down driving the output signal in response to the driving signal; a switching unit switching to transfer the driving signal in response to the level of the output signal; and a sub driving unit pull-down or pull-up driving the output signal in response to the driving signal when the driving signal is transferred from the switching unit.

Herein, the main driving unit comprises a pull-up transistor pull-up driving the output signal in response to the driving signal; and a pull-down transistor pull-down driving the output signal in response to the driving signal.

Further preferably, the switching unit comprises a first switch switching to transfer the driving signal corresponding to the pull-up driving in response to the level of the output signal; and a second switch switching to transfer the driving signal corresponding to the pull-down driving in response to the level of the output signal. The first switch comprises a first MOS transistor inputting the output signal at a gate thereof and switching to transfer the driving signal corresponding to the pull-up driving, and the second switch comprises a second MOS transistor inputting the output signal at a gate thereof and switching to transfer the driving signal corresponding to the pull-down driving.

Further, the sub driving unit comprises a pull-up transistor pull-up driving the output signal in response to the driving signal transferred from the switching unit; and a pull-down transistor pull-down driving the output signal in response to the driving signal transferred from the switching unit.

Meanwhile, the input signal corresponds to an internal data of a semiconductor memory device.

A buffer circuit according to other embodiment of the present invention comprises a pre-driver outputting a pull-up driving signal or a pull-down driving signal in response to an input signal; a pull-up driver pull-up driving the output signal in response to the pull-up driving signal wherein the pull-up driver having a strength of the pull-up driving adjusted in response to a level of the output signal; and a pull-down driver pull-down driving the output signal in response to the pull-down driving signal wherein the pull-down driver having a strength of pull-down driving adjusted in response to a level of the output signal.

Herein, the pull-up driver comprises a sub pull-up driving unit sub pull-up driving, in response to a level of the output signal, to adjust the pull-up driving strength.

Further, the pull-up driver comprise a main pull-up transistor pull-up driving the output signal in response to the pull-up driving signal; a switch switching to transfer the pull-up driving signal in response to the level of the output signal; and a sub pull-up transistor pull-up driving the output signal in response to the pull-up driving signal transferred from the switch.

Herein, the switch comprises a MOS transistor inputting the output signal at a gate thereof and switching to transfer the pull-up driving signal.

Further, the pull-down driver comprises a sub pull-down driving unit sub pull-down driving, in response to the level of the output signal, to adjust the pull-down driving strength.

Further, the pull-down driver comprise a main pull-down transistor pull-down driving the output signal in response to the pull-down driving signal; a switch switching to transfer the pull-down driving signal in response to the level of the output signal; and a sub pull-down transistor pull-down driving the output signal in response to the pull-down driving signal transferred from the switch. The switch comprises a MOS transistor inputting the output signal at a gate thereof and switching to transfer the pull-down driving signal.

Meanwhile, the input signal corresponds to an internal data of a semiconductor memory device.

### BRIEF DESCRIPTION OF THE DRAWINGS

FIG. 1 is a diagram showing a buffer circuit used as an output buffer of a semiconductor memory device according to prior art.

FIG. 2 is a diagram showing a buffer circuit according to the present invention.

FIG. 3 is a diagram showing a driving strength of the buffer circuit and a variance of level [V] of an output signal OUT depending on time [t] according to the present invention.

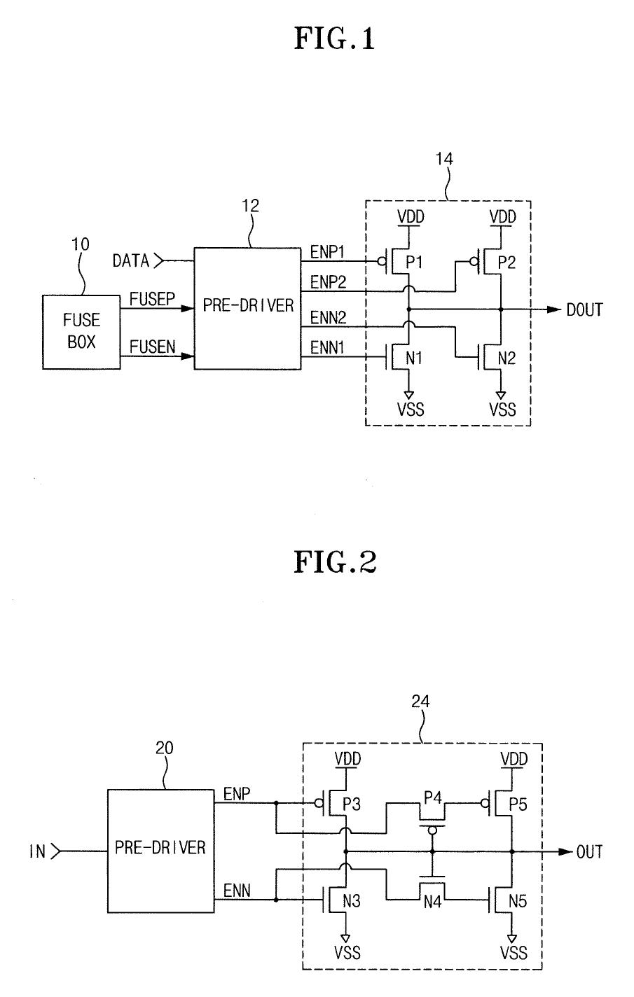

### DESCRIPTION OF SPECIFIC EMBODIMENTS

Hereinafter, preferred embodiments of the present invention will be described in detail with reference to the accompanying drawings.

The present invention discloses a buffer circuit inputting a prescribed signal and using pull-up or pull-down driving operations to output an output signal, in which pull-up or pull-down driving strength of the buffer circuit is adjusted in accordance with a level of the output signal.

Specifically, referring to FIG. 2, a buffer circuit according to an embodiment of the present invention comprises a pre-driver 20 and an output driver 24.

The pre-driver 20 outputs any one of a pull-up driving signal ENP and a pull-down driving signal ENN in response to the input signal IN. Herein, if the buffer of an embodiment of the present invention is used as the buffer circuit of a semiconductor memory device, the input signal IN can correspond to an internal data.

As an example, the pre-driver 20 can be configured to pull-down drive to output the pull-down driving signal ENN when the input signal IN is at a high level. Likewise, the pre-driver 20 can be configured to pull-up drive to output the pull-up driving signal ENP when the input signal IN is at a low level.

The output driver 24 outputs an output signal OUT, in which it pull-up drives the output signal OUT in response to the pull-up driving signal ENP when the pull-up driving signal ENP is output from the pre-driver 20. In a similar manner, the output driver 24 outputs the output signal OUT, in which it pull-down drives the output signal OUT in response to the pull-down driving signal ENN when the pull-down driving signal ENN is output from the pre-driver 20. Further, the output driver 24 is allowed to adjust the pull-up driving strength and the pull-down driving strength in accordance with the level of the output signal OUT.

As an example, the output driver 24 comprises a main driving unit outputting the output signal OUT by pull-up or pull-down driving in response to the pull-up driving signal ENP or the pull-down driving signal ENN, a switching unit switching to transfer the pull-up driving signal ENP or the pull-down driving signal ENN in accordance with the level of the output signal OUT, and a sub-driving unit pull-up or pull-down driving the output signal OUT additionally in response to the pull-up driving signal ENP or the pull-down driving signal ENN transferred from the switching unit.

Herein, the main driving unit comprises a pull-up transistor pull-up driving the output signal OUT in response to the pull-up driving signal ENP and a pull-down transistor pull-down driving the output signal OUT in response to the pull-down driving signal ENN. The pull-up transistor can correspond to a PMOS transistor P3 inputting the pull-up driving signal ENP at a gate thereof and pull-up driving the output signal OUT to a level approaching or equally that of a power supply voltage VDD, and the pull-down transistor can correspond to a NMOS transistor N3 inputting the pull-down driving signal ENN at a gate thereof and pull-down driving the output signal OUT to a level approaching or equally that of a ground voltage VSS.

Further, the switching unit includes a first switch switching to transfer the pull-up driving signal ENP in accordance with the level the output signal OUT and a second switch switching to transfer the pull down driving signal ENN in accordance with the level of the output signal OUT. The first switch can correspond to a PMOS transistor P4 inputting the output signal OUT at a gate thereof and switching to transfer the pull-up driving signal ENP. The second switch can correspond to an NMOS transistor N4 inputting the output signal OUT at a gate thereof and switching to transfer the pull-down driving signal ENN.

Further, the sub-driving unit comprises a pull-up transistor pull-up driving the output signal OUT in response to a pull-up driving signal ENP transferred from the switching unit. The sub-driving unit also comprises a pull-down transistor pull-down driving the output signal OUT in response to the pull-down driving signal ENN transferred from the switching unit. The pull-up transistor can correspond to a PMOS transistor P5 inputting the pull-up driving signal ENP transferred from the PMOS transistor P4 at a gate thereof and pull-up driving the output signal OUT to a level approaching or equivalent to that of the power supply voltage VDD. The pull-down transistor can correspond to a NMOS transistor N5 inputting the pull-down driving signal ENN transferred from the NMOS transistor N4 at a gate thereof and pull-down driving the output signal OUT to a level approaching or equivalent to that of the ground voltage VSS.

As another example, the output driver 24 can be configured to comprise a pull-up driver pull-up driving the output signal OUT in response to the pull-up driving signal ENP and having the pull-up driving strength controlled in accordance with the level of the output signal OUT. Further, the output driver 24 can be configured to comprise a pull-down driver pull-down driving the output signal OUT in response to the pull-down driving signal ENN and having the pull-down driving strength controlled in accordance with the level of the output signal OUT.

Herein, the pull-up driver comprises a main pull-up transistor pull-up driving the output signal OUT in response to the pull-up driving signal ENP; a switch switching to transfer the pull-up driving signal ENP in accordance with the level of the output signal OUT; and a sub pull-up transistor additionally pull-up driving the output signal OUT in response to the pull-up driving signal ENP transferred from the switch. The main pull-up transistor can correspond to a PMOS transistor P3, the switch can correspond to a PMOS transistor P4, and the sub pull-up transistor can correspond to a PMOS transistor P5.

Further, the pull-down driver comprises a main pull-down transistor pull-down driving the output signal OUT in response to the pull-down driving signal ENN; a switch switching to transfer the pull-down driving signal ENN in accordance with the level of the output signal OUT, and a sub pull-down transistor additionally pull-down driving the output signal OUT in response to the pull-down driving signal ENN transferred from the switch. The main pull-down transistor can correspond to an NMOS transistor N3. The switch can correspond to an NMOS transistor N4. The sub pull-down transistor can correspond to an NMOS transistor N5.

Hereinafter, referring to FIG. 2, an operation of the buffer circuit according to the present invention will be specifically described.

First, if the input signal IN is input as a low level, the pre-driver 20 outputs the pull-up driving signal ENP and the output driver 24 inputs the pull-up driving signal ENP and pull-up drives it. That is, if the pull-up driving signal ENP is input to a gate of the PMOS transistor P3, the PMOS transistor P3 pull-up drives to cause the output signal OUT to be increased to substantially the level of that of the power supply voltage VDD. At this time, if a size of the PMOS transistor P3 is large enough to make the output signal OUT high level rapidly, the PMOS transistor P4 remains at a turn-off state so that the driving strength of the output driver 24 is not substantially varied.

Meanwhile, if the size of the PMOS transistor P3 is not large enough, the PMOS transistor P4 is turned on while the output signal OUT remains at a low level. Herein, the low level is defined as a level lower than a threshold voltage of the PMOS transistor P4. And, as the PMOS transistor P4 is turned on, the pull-up driving signal ENP is transferred to a gate of the PMOS transistor P5 so that the PMOS transistor P5 is turned on. That is, since both of the PMOS transistor P3 and the PMOS transistor P5 are turned on while the output signal OUT is at a low level state, the driving strength of the output driver 24 increases to enable the output signal OUT to be increased to a high level more rapidly.

Next, if the input signal is input as a low level, the pre-driver 20 outputs the pull-down driving signal ENN, and the output driver 24 inputs the pull-down driving signal ENN and pull-down drives it. That is, as the pull-down driving signal ENN is input to a gate of the NMOS transistor N3, then the NMOS transistor N3 pull-up drives to cause the output signal OUT to be decreased to the level of the ground voltage VSS. At this time, if a size of the NMOS transistor N3 is large enough to make the output signal OUT low level rapidly, the NMOS transistor N4 remains at a turn-off state so that the driving strength of the output driver 24 is not substantially varied.

Meanwhile, in the event that if the size of the NMOS transistor N3 is not large enough, then the NMOS transistor N4 is turned on while the output signal OUT remains at a high level state. Herein, the high level remains a level larger than the threshold voltage of the NMOS transistor N4. Whereupon as the NMOS transistor N4 is turned on, then the pull-down driving signal ENN is transferred into a gate of the NMOS transistor N5 to cause the NMOS transistor N5 to turn on. That is, since both of the NMOS transistor N3 and the NMOS transistor N5 are turned on while the output signal OUT is at a high level state, then the driving strength of the output driver 24 increases to enable the output signal OUT to be decreased to a low level more rapidly.

As described above, the buffer circuit according to the present invention operates in a manner such that if the output signal OUT does not reach to a prescribed level rapidly because the driving strength of the main transistors P3, N3 of the output driver 24 is not sufficient. However, the driving strength is increased by the sub transistors P5, N5 which are automatically turned on in accordance with the level of the output signal OUT to enable the output signal OUT to reach to a prescribed level rapidly.

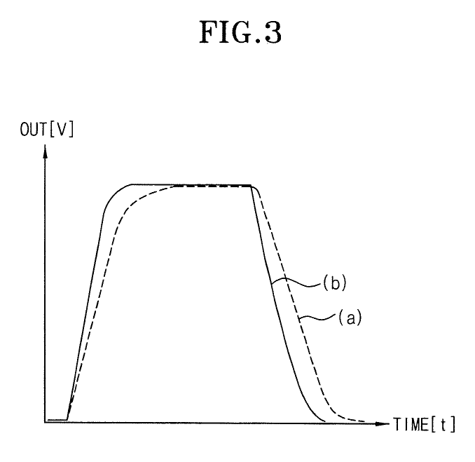

That is, as shown in FIG. 3, if only main transistors P3, N3 are driven without sub transistors P5, N5, when the driving strength of the main transistors P3 N3 is not sufficient, then a rising time and a falling time until the output signal OUT reaches to a prescribed level is delayed as shown in ‘(a)’ relative to ‘(b)’.

However, if the sub transistors P5, N5 are equipped to be automatically turned on in accordance with the level of the output signal OUT according to the present invention, then the main transistors P3, N3 and the sub transistors P5, N5 are turned on together when the driving strength of the main transistors P3, N3 is not sufficient. Accordingly, the driving strength increases so that the rising time and the falling time of the output signal OUT can be reduced as depicted in ‘(b)’ relative to ‘(a)’.

Further, since the buffer circuit according to the present invention additionally includes only transistors P4, N4 switching to transfer the pull-up driving signal ENP or the pull-down driving signal ENN in accordance with the level of the output signal OUT for the purpose of driving the sub transistors P5, N5, then a reduction in the area afforded for the fuse box 10 relative to prior known latch circuit configurations for the fuse box 10.

Further, since the sub transistors P5, N5 are turned on automatically in accordance with the level of the output signal OUT to adjust the driving strength according to the buffer circuit of the present invention, an advantage can be realized in that there is no need to cut the fuse especially as to what is already known in the prior art.

Further, since the driving strength can be automatically adjusted in accordance with the level of the output signal OUT without other operation (i.e., fuse cutting operation), then the time of adjusting the driving strength can be reduced.

The present invention can adjust the driving strength of the driver with less area, by providing the buffer circuit adjusting the driving strength of the driver with a switch switching to transfer the driving signal in accordance with the level of the output signal and by providing transistors additionally driving the signal in accordance with the output from the switch.

Further, the present invention can provide a simple way of adjusting driving strength of the driver by providing buffer circuit automatically performing the pull-up or pull-down driving in accordance with the level of the output signal.

Further, the present invention can have an advantage of reducing the time to adjust the driving strength, since additional operation of adjusting the driving strength of the driver is not needed by providing the buffer circuit which can cause the driving strength of the driver to be adjusted automatically in accordance with the level of the output signal.

Those skilled in the art will appreciate that the specific embodiments disclosed in the foregoing description may be readily utilized as a basis for modifying or designing other embodiments for carrying out the same purposes of the present invention. Those skilled in the art will also appreciate that such equivalent embodiments do not depart from the spirit and scope of the invention as set forth in the appended claims.

What is claimed is:

1. A buffer circuit, comprising:
a pre-driver outputting a driving signal in response to an input signal; and
an output driver driving an output signal in response to the driving signal and having a strength of the driving adjusted in response to a level of the output signal.

2. The buffer circuit as set forth in claim 1, wherein the pre-driver outputs a pull-up driving signal or a pull-down driving signal as the driving signal of the pre-driver to correspond with a level of the input signal.

3. The buffer circuit as set forth in claim 1, wherein the output driver comprises a sub-driving unit which sub-drives the output signal in response to a level of the output signal to adjust the driving strength.

4. The buffer circuit as set forth in claim 1, wherein the output driver comprises:
a main driving unit pull-up driving or pull-down driving the output signal in response to the driving signal;
a switching unit switching to transfer the driving signal in response to the level of the output signal; and
a sub driving unit pull-down or pull-up driving the output signal in response to the driving signal when the driving signal is transferred from the switching unit.

5. The buffer circuit as set forth in claim 4, wherein the main driving unit comprises:
a pull-up transistor pull-up driving the output signal in response to the driving signal; and
a pull-down transistor pull-down driving the output signal in response to the driving signal.

6. The buffer circuit as set forth in claim 4, wherein the switching unit comprises:
a first switch switching to transfer the driving signal corresponding to the pull-up driving in response to the level of the output signal; and
a second switch switching to transfer the driving signal corresponding to the pull-down driving in response to the level of the output signal.

7. The buffer circuit as set forth in claim 6, wherein the first switch comprises a first MOS transistor inputting the output signal at a gate thereof and switching to transfer the driving signal corresponding to the pull-up driving, and the second switch comprises a second MOS transistor inputting the output signal at a gate thereof and switching to transfer the driving signal corresponding to the pull-down driving.

8. The buffer circuit as set forth in claim 4, wherein the sub driving unit comprises:
a pull-up transistor pull-up driving the output signal in response to the driving signal transferred from the switching unit; and
a pull-down transistor pull-down driving the output signal in response to the driving signal transferred from the switching unit.

9. The buffer circuit as set forth in claim 1, wherein the input signal corresponds to an internal data of a semiconductor memory device.

10. A buffer circuit comprising:
a pre-driver outputting a pull-up driving signal or a pull-down driving signal in response to an input signal;
a pull-up driver pull-up driving a output signal in response to the pull-up driving signal and having a strength of the pull-up driving adjusted in response to a level of the output signal; and
a pull-down driver pull-down driving the output signal in response to the pull-down driving signal and having a strength of the pull-down driving adjusted in response to a level of the output signal.

11. The buffer circuit as set forth in claim 10, wherein the pull-up driver comprises a sub pull-up driving unit sub pull-up driving in response to a level of the output signal to adjust the pull-up driving strength.

12. The buffer circuit as set forth in claim 10, wherein the pull-up driver comprises:
a main pull-up transistor pull-up driving the output signal in response to the pull-up driving signal;
a switch switching to transfer the pull-up driving signal in response to the level of the output signal; and
a sub pull-up transistor pull-up driving the output signal in response to the pull-up driving signal transferred from the switch.

13. The buffer circuit as set forth in claim 12, wherein the switch comprises a MOS transistor inputting the output signal at a gate thereof and switching to transfer the pull-up driving signal.

14. The buffer circuit as set forth in claim 10, wherein the pull-down driver comprises a sub pull-down driving unit sub pull-down driving in response to the level of the output signal to adjust the pull-down driving strength.

15. The buffer circuit as set forth in claim 10, wherein the pull-down driver comprises:
a main pull-down transistor pull-down driving the output signal in response to the pull-down driving signal;
a switch switching to transfer the pull-down driving signal in response to the level of the output signal; and
a sub pull-down transistor pull-down driving the output signal in response to the pull-down driving signal transferred from the switch.

16. The buffer circuit as set forth in claim 15, wherein the switch comprises a MOS transistor inputting the output signal at a gate thereof and switching to transfer the pull-down driving signal.

17. The buffer circuit as set forth in claim 10, wherein the input signal corresponds to an internal data of a semiconductor memory device.
